(19) United States
(12) Patent Application Publication
(10) Pub. No.: US 2018/0190902 A1
(43) Pub. Date: Jul. 5, 2018

(54) MAGNETIC TUNNEL JUNCTION DEVICE

(71) Applicant: IMEC VZW, Leuven (BE)

(72) Inventors: Kevin Garello, Leuven (BE); Siddharth Rao, Leuven (BE)

(21) Appl. No.: 15/857,168

(22) Filed: Dec. 28, 2017

(30) Foreign Application Priority Data
Dec. 29, 2016 (EP) 16207339.9

(51) Int. Cl. H01L 43/12; H01L 43/02

(52) U.S. Cl. CPC H01L 43/12; G11C 11/161; H01L 43/02

(57) ABSTRACT

The disclosed technology generally relates to magnetic devices, and more particularly to magnetic tunnel junction (MTJ) devices, and methods of forming the MTJ devices. In one aspect, a method of forming a magnetic tunnel junction (MTJ) device comprises providing a stack of layers comprising, in a top-down direction, a first magnetic layer having a fixed magnetization direction, a barrier layer, and a second magnetic layer having a switchable magnetization direction with respect to the fixed magnetization direction of the first magnetic layer. The method additionally comprises etching the stack of layers to form a pillar comprising at least the first magnetic layer. The method additionally comprises forming at least one trench in the second magnetic layer adjacent the pillar. The method further comprises processing at least one region of the second magnetic layer peripheral to the at least one trench with respect to the pillar, such that the at least one region obtains an in-plane magnetic anisotropy.

### CROSS-REFERENCE TO RELATED APPLICATIONS

This application claims foreign priority to European Patent Application No. 16207339.9, filed on Dec. 29, 2016, the content of which is incorporated by reference herein in its entirety.

### BACKGROUND

### Field

The disclosed technology generally relates to magnetic devices, and more particularly to magnetic tunnel junction (MTJ) devices, and methods of forming the MTJ devices.

### Description of the Related Technology

Conventional random access memory devices, e.g., dynamic random access memory (DRAM), are generally volatile. That is, information stored in the memory device may be lost when power is turned off. With the advancement of magnetic device technologies, there has been a considerable growing interest in using spintronics to develop non-volatile magnetic random access memories (MRAMs). Some advanced MRAM devices comprise magnetic tunnel junctions (MTJs), which comprise two ferromagnetic (FM) layers separated by a barrier layer, which can be an insulating layer. If the insulating layer is sufficiently thin, e.g., a few nanometers, electrons can quantum-mechanically tunnel from one ferromagnetic layer to the other, thereby inducing a change in orientation of the magnetization direction of one of the FM layers. The resistance of the MTJ can be dependent on the relative orientations of magnetization directions of the two FM layers, which value determines the state of a memory cell. This mechanism is referred to in the industry as tunnel magnetoresistance (TMR).

In an MTJ-based memory device, the reading operation is performed by measuring the TMR. The writing operation can be achieved by spin-transfer torque (STT), representing a transfer of spin angular momentum from a reference FM layer to a free FM layer of the MTJ. These STT-MRAM devices are sometimes referred to as two-terminal devices. When configured as a two-terminal device, the STT-based writing may be performed using the same two terminals and the current path as those used to perform the TMR-based reading. Recently, there has been a growing interest in three-terminal MTJs, which decouple the writing and reading current paths. Some three-terminal devices may allow for relatively higher operation (read and/or write) speeds and higher reliability, e.g., improved endurance cycling capability, compared to two-terminal STT-MTJs. In some three-terminal devices, the switching of the magnetization in the free FM layer can be facilitated or mediated by spin-orbit torques (SOTs), which may be generated by conducting a current through a layer arranged adjacent to the free FM layer. Based on the recent studies, SOT-MRAM devices have been suggested for relatively high speed applications.

However, it should be noted that the SOT concept relies on application of an external field in the plane of the MTJ and along the SOT current direction, in order to break the symmetry of the system, and to obtain a deterministic magnetization switching. The inventors have accordingly realized that there is a desire and a need in the industry to provide a SOT-MTJ element which is switchable without the need of providing an external field. Various embodiments disclosed herein address these and other needs.

### SUMMARY OF CERTAIN INVENTIVE ASPECTS

It is an object of the disclosed technology to mitigate the above-mentioned problems, and to provide an efficient SOT-MTJ device.

This and other objects are achieved by providing MTJ devices and methods of forming such MTJ devices having the features in the independent claims. Preferred embodiments are defined in the dependent claims.

Hence, according to a first aspect of the disclosed technology, there is provided a method of forming a magnetic tunnel junction (MTJ) device. The method comprises providing a stack of layers comprising, in a top-down direction, a first magnetic layer having a fixed magnetization direction, a barrier layer, and a second magnetic layer being configured to switch its magnetization direction with respect to the fixed magnetization direction of the first magnetic layer. The method further comprises etching the stack of layers such that a pillar is formed and such that at least one trench is created in the second magnetic layer adjacent the pillar. The method further comprises processing of at least one region of the second magnetic layer peripheral of the at least one trench with respect to the pillar, such that the at least one region obtains an in-plane magnetic anisotropy.

According to a second aspect of the disclosed technology, there is provided an alternative method of forming a MTJ device. The method comprises providing a stack of layers, at least comprising, in a top-down direction, a first magnetic layer having a fixed magnetization direction, a barrier layer, and a second magnetic layer being configured to switch its magnetization direction with respect to the fixed magnetization direction of the first magnetic layer. The stack of layers further includes a pinning layer arranged above the first magnetic layer for fixing the magnetization direction of the first magnetic layer. The method further comprises etching the stack of layers, at least until the first magnetic layer to form a pillar. The method further comprises processing a portion of the second magnetic layer extending outside the pillar as viewed in a horizontal plane, such that the portion obtains an in-plane magnetic anisotropy. Moreover, the method comprises de-magnetizing, of the portion of the second magnetic layer, at least one region located adjacent the pillar, as viewed in a horizontal plane. Thereby, a de-magnetized region of the second magnetic layer, located adjacent to the pillar, and a portion of the second magnetic layer, peripheral of the de-magnetized region, having an in-plane magnetic anisotropy are formed. By the term “horizontal plane” is here meant a plane parallel to a main surface or main plane of extension of the second magnetic layer. By the term “de-magnetizing”, it is here meant that the portion or region subjected to the de-magnetization becomes non-magnetic or substantially non-magnetic in non-reversible manner. According to an alternative method, the last two steps after the etching step may be reversed. In other words, after the etching, there may be provided the step of de-magnetizing, of the portion of the second magnetic layer, at least one region located adjacent the pillar, and thereafter, a processing of the portion of the second magnetic layer such that the portion obtains an in-plane magnetic anisotropy.

According to a third aspect of the disclosed technology, there is provided a MTJ device comprising a stack of layers, at least comprising, in a top-down direction, a first magnetic layer having a fixed magnetization direction, a barrier layer, and a second magnetic layer being configured to switch its magnetization direction with respect to the fixed magnetization direction of the first magnetic layer. At least the first magnetic layer, and, optionally, the barrier layer may constitute a pillar, and a portion of the second magnetic layer extends from the pillar in a horizontal plane. At least one first region of the portion of the second magnetic layer comprises at least one trench adjacent the pillar. Furthermore, of the portion of the second magnetic layer, at least one second region peripheral of the at least one trench with respect to the pillar, have an in-plane magnetic anisotropy.

According to a fourth aspect of the disclosed technology, there is provided a MTJ device, comprising a stack of layers, at least comprising, in a top-down direction, a first magnetic layer having a fixed magnetization direction, a barrier layer, and a second magnetic layer being configured to switch its magnetization direction with respect to the fixed magnetization direction of the first magnetic layer. The stack of layers further includes a pinning layer arranged above the first magnetic layer for fixing the magnetization direction of the first magnetic layer. At least the pinning layer, and optionally, the first magnetic layer, and optionally, the barrier layer, constitutes a pillar. The second magnetic layer comprises at least one first portion located outside (and adjacent) the pillar, as viewed in a horizontal plane, wherein the at least one first portion is de-magnetized. The second magnetic layer comprises at least one second portion located peripheral of the at least one first portion with respect to the pillar, wherein the at least one second portion has an in-plane magnetic anisotropy.

Thus, the disclosed technology is based on the idea of providing field-free switching in (SOT)-MTJ devices and/or methods of forming such MTJ devices. To realize this concept, the second magnetic (free) layer of the MTJ stack comprises an inner portion having an out-of-plane magnetic anisotropy and at least one outer portion having an in-plane magnetic anisotropy. The inner and outer portions of the second magnetic layer are (physically) separated by from each other, either by a trench or a de-magnetized region. It will be appreciated that, in the case of providing a continuous second magnetic layer, e.g., without a trench or without a de-magnetized region, there is a spin-to-spin coupling between the magnetizations of the inner portion and the outer portion. It will be appreciated that this coupling generates relatively complex magnetization dynamics. More specifically, the coupling is accompanied by an in-plane to out-of-plane magnetic transition, and it generates relatively complex magnetization dynamics of both the inner and outer portion of the second magnetic layer. As a consequence, the switching is relatively difficult to control. Although it is still possible to deterministically control the magnetization by providing a continuous second magnetic layer, it should be noted that the magnetization is relatively sensitive with regard to several parameters of the SOT (e.g., the amplitude, the ratio between field-like and damping-like components, the strength of the Dzyaloshinskii-Moriya interaction, the part of the outer portion being exposed to the SOT current, etc.). In contrast, by providing a magnetic separation in the second magnetic layer, according to the disclosed technology, the control of the switching is improved. It will be appreciated that the level of control of the switching according to the disclosed technology may be comparable to that of SOT switching by means of an external field.

It will be appreciated that the second magnetic (free) layer is already a part of the MTJ stack, and the disclosed technology is thereby advantageous in that an adding of auxiliary layers, which could complicate the method of the creating the MTJ device, may be superfluous. The disclosed technology is furthermore advantageous in that the properties of an underlying SOT-generating layer of the stack may be chosen in a relatively unrestricted manner. For example, a SOT-generating layer may be provided which generates relatively large SOTs. Moreover, the disclosed technology is advantageous in that the anisotropy of the second magnetic layer may be controlled and/or tuned to a relatively high extent.

It should be noted that mentioned advantages of the method(s) of the first and/or second aspects of the disclosed technology also hold for the MTJ device(s) according to the third and/or fourth aspects of the disclosed technology.

According to an embodiment of the disclosed technology, the step of etching further comprises etching the stack of layers until the second magnetic layer to form a pillar, whereby a portion of the second magnetic layer extends from the pillar in a horizontal plane. The step further comprises patterning the portion of the second magnetic layer and, thereafter, etching the portion adjacent the pillar such that at least one trench is created. The present embodiment is advantageous in that the patterning (masking) of the second magnetic layer leads to a convenient and/or efficient etching of the trench(es) in the layer.

It will be appreciated that the step of etching may further comprise creating a trench on either side of the pillar. Moreover, the step of processing may further comprise processing of a respective region of the second magnetic layer peripheral of the respective trench with respect to the pillar, such that the respective region obtains an in-plane magnetic anisotropy.

As used herein, the expression a trench, a region or a portion being created, formed or otherwise provided “on either side of the pillar” may mean that a trench/region/portion is provided on at least two sides of the pillar, as viewed in a horizontal direction (for instance corresponding to a direction of an in-plane SOT-current through the device).

A trench/region/portion may be formed to extend about the pillar. A trench/region/portion may be formed to extend partially or completely about the pillar. A trench/region/portion may accordingly be formed on either side of the pillar by two different parts of the same trench/region/portion, the two parts being formed on either side of the pillar.

According to an embodiment of the method of disclosed technology, in case of a portion of the second magnetic layer remaining under the at least one trench after the step of etching, there is provided a step of de-magnetizing at least a part of the portion of the second magnetic layer. In other words, after the etching of one or more trenches in the second magnetic layer, there may be remnant material of the second magnetic layer under the trench(es). In the present embodiment, at least a part of this remnant material may be de-magnetized. The present embodiment is advantageous in that the portion of the second magnetic layer, subjected to a trench and a de-magnetizing process, may hereby be de-magnetized to an even higher extent.

The step of de-magnetizing may be a process step separate from, i.e. performed in addition to, the processing of the at least one region of the second magnetic layer. Alternatively, the act of processing of at least one region of the second magnetic layer peripheral of the at least one trench with respect to the pillar may include processing the at least one region and a portion of the second magnetic layer remaining under the at least one trench after the step of etching. Thereby the number of process steps may be limited.

According to an embodiment of the disclosed technology, the method further comprises forming an electrically insulating medium in the at least one trench. For example, the trench(es) may be subjected to an insulating medium in a process. Alternatively, one or more electrically insulating media (e.g., comprising at least one oxide) may be provided in the trench(es).

According to an embodiment of the disclosed technology, the step of processing of at least one region of the second magnetic layer comprises at least one of an oxidation and an irradiation of the at least one region. In other words, an oxidation and/or an irradiation of the one or more region of the second magnetic layer may be conducted, such that the regions(s) obtain an in-plane magnetic anisotropy.

According to an embodiment of the disclosed technology, the step of etching further comprises etching the stack of layers until the second magnetic layer to form a pillar, whereby a portion of the second magnetic layer extends from either side of the pillar. Furthermore, the step of de-magnetizing further comprises de-magnetizing a respective region located on either side of the pillar.

According to an embodiment of the device of the disclosed technology, there is provided a trench on either side of the pillar and a respective second region of the second magnetic layer peripheral of the respective trench.

According to an embodiment of the device of the disclosed technology, in case of a portion of the second magnetic layer being provided under the at least one trench, at least a part of the portion of the second magnetic layer is de-magnetized.

According to an embodiment of the device of the disclosed technology, at least one of the trenches is at least partially provided with an electrically insulating medium. For example, the electrically insulating medium may comprise one oxide. Alternatively, the electrically insulating medium may comprise a non-oxide compound, e.g., SiN.

According to an embodiment of the device of the disclosed technology, the second magnetic layer comprises one of the at least one first portion located on either side of the pillar and one of the at least one second portion peripheral of a respective one of the at least one first portion.

According to an embodiment of the disclosed technology, at least one of a width and a length of the device in a plane thereof is larger than the height of the stack. The present embodiment is advantageous in that the magnetization hereby may be maximal in the plane of the MTJ device. In other words, the de-magnetizing field may be maximal along a vertical axis z and minimal in the x-y-plane of the device.

Further objectives of, features of, and advantages with, the disclosed technology will become apparent when studying the following detailed disclosure, the drawings and the appended claims. Those skilled in the art will realize that different features of the disclosed technology can be combined to create embodiments other than those described in the following.

### BRIEF DESCRIPTION OF THE DRAWINGS

This and other aspects of the disclosed technology will now be described in more detail, with reference to the appended drawings showing embodiment(s) of the invention.

FIG. 1 is a schematic cross-sectional view of a magnetic tunnel junction (MTJ) device according to some embodiments.

FIG. 2 is a schematic cross-sectional view of a MTJ device according to some other embodiments.

FIG. 3 is a schematic plan view of a MTJ device according to some other embodiments.

### DETAILED DESCRIPTION OF CERTAIN ILLUSTRATIVE EMBODIMENTS

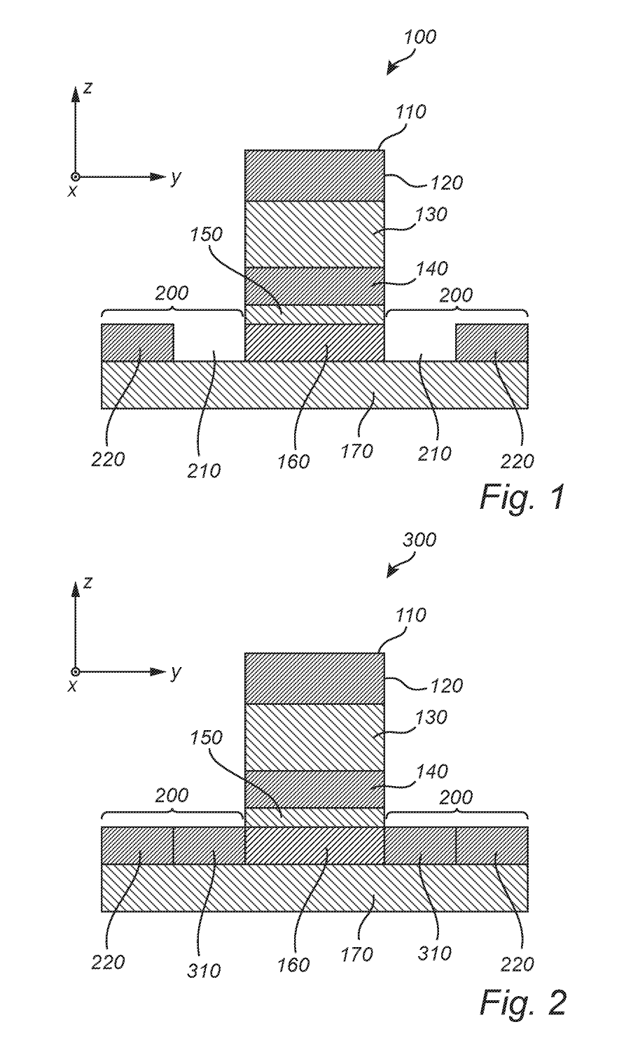

FIG. 1 is a schematic view of a magnetic tunnel junction (MTJ) device 100, according to an embodiment of the disclosed technology. The device 100 comprises a stack of layers 110 arranged along a vertical axis (z-axis) of the device 100. The structure of the device 100 is shown in a cross-section of the stacking direction of the layers 110. It will be appreciated that the illustrated device 100 may represent a portion of the device 100, and that various layers including the layers 110 may extend laterally/horizontally beyond the illustrated portions. In addition, the illustrated device 100 may represent a final device or an intermediate structure prior to forming the final device. Furthermore, it should be noted that for the purpose of clarity, the various layers 110 and other features of the stacks are not drawn to scale and their relative dimensions, in particular their thickness, may differ from a physical stack.

The stack of layers 110 comprises, in a top-down direction, a hard mask 120, which may be used to define the size and/or shape of the stack of layers 110 and therefore may not be present in the final device, a pinning layer comprising a synthetic antiferromagnetic (SAF) layer 130, which may serve to pin a first magnetic layer 140 (also referred to herein as reference FM layer) having a fixed magnetization direction, a barrier layer 150, a second magnetic layer 160 (also referred to herein as free FM layer) being configured to switch its magnetization direction with respect to the fixed magnetization direction of the first magnetic layer 140, and a spin-orbit torque (SOT)-generating layer 170, which may be formed on a substrate, e.g., a semiconductor substrate. It will be appreciated that in the illustrated embodiment, the SAF layer 130 and the first and second magnetic layers 140, 160 are magnetic materials that possess perpendicular magnetic anisotropy (PMA), or a magnetic anisotropy in a direction perpendicular to the extension direction of the respective magnetic layer. In some embodiments, the SAF layer 130 may in turn comprise a plurality of layers, for example first and second magnet layers separated by a thin metal layer. In some configurations, the SAF layer 130 may serve to compensate the stray field generated by the first magnetic layer 140 on the second magnetic layer 160. This stray field compensation may advantageously optimize the performance of the MTJ device 100.

Examples of materials for the first magnetic layer 140 include Fe, Co, CoFe, FeB, CoB, and CoFeB. Ni, FePt, CoGd, CoFeGd, CoFeTb, CoTb may also be examples of materials for the first magnetic layer 140.

It will be appreciated that, in some embodiments, the first magnetic layer 140 may have a multi-layer structure including combinations of the afore-mentioned materials. The second magnetic layer 160 may include Fe, Co, FeB, CoB, CoFe, CoFeB, Ni, FePt, CoGd, CoFeGd, CoFeTb and/or CoTb and may also have a multi-layer structure including combinations of the afore-mentioned materials. The barrier layer 150 may include a layer of a dielectric material, for instance MgO, AlOx, MgAlOx or MgTiOx and may be adapted to allow electrons to tunnel between the first magnetic layer 140 and the second magnetic layer 160.

The SOT-generating layer 170 may include a layer of electrically conducting material configured for relatively large spin-orbit coupling. The SOT-generating layer 170 may be non-magnetic. Some example materials for the SOT-generating layer 170 include metals such as Ta, W, Pt, Pd, Jr, IrMn, PtMn, WOx, FeMn, NiMn or topological insulators such as Bi₂Se₃ or transition metal dichalcogenide (TMD) such as MoS₂, WTe₂. The SOT-generating layer 170 may also have a multi-layer structure, e.g., including a combination of any of the above-mentioned materials. The SOT-generating layer 170 may have a thickness of 10 nm or less, 5 nm or less, or in a range of 5-10 nm, and may be formed using a suitable deposition technique, such as evaporation or sputtering.

Because the first magnetic layer 140, which may be a fixed FM layer, is arranged above the second magnetic layer 160, the device 100 may sometimes be referred to as a top-pinned MTJ device. The pinning of the first magnetic layer 140 may be achieved via ferromagnetic exchange coupling through a spacer layer with a hard magnetic layer. The spacer may include, e.g., Ta, W, Mo, CoFeBTa, CoFeBW, CoBTa, FeBTa, CoBW, FeBW, FeTa, CoTa, FeW, TaW, or combinations thereof. In some cases, pinning may be achieved by coupling the first magnetic layer 140 through a spacer layer to a Co/Ru/hard magnetic layer pinning system. The hard magnetic layer may include a combination of a Co-layer and a Pt-layer, a combination of a Co-layer and a Ni-layer, a combination of a Co-layer and a Pd-layer, MnGe alloys, MnGa alloys, CoPt alloys, CoNi alloys or FePt alloys.

While not illustrated for clarity, the first magnetic layer 140 and the SOT-generating layer 170 may be electrically connected to a top electrode and a bottom electrode, respectively. By conducting a current through the SOT-generating layer 170, a torque may be exerted on the magnetization of the first magnetic layer 140, and the magnetization of the first magnetic layer 140 may be switched in a relatively effective and fast way.

The hard mask 120, formed above the stack of layers 110, may include TiN, TaN, TiTaN and spin-on-carbon/spin-on-glass materials. The hard mask 120 may for instance have a rectangular or round shape as viewed in a top-down direction. The hard mask 120 may define the size and shape of the stack of layers 110 of the MTJ device 100 by etching regions of the stack of layers 110 stack which are exposed by the hard mask 120. The etching techniques may include anisotropic etch processes such as a reactive-ion-etching (RIE) process or an ion-beam-etching (IBE) process. Because the hard mask 120 serves as a masking layer during patterning, the stack of layers 110, the hard mask layer 120 may not be present in some final devices. On the other hand, when formed of a conducting material, the hard mask layer 120 maybe left in some other final devices. In FIG. 1, the stack of layers 110 has been etched down to at least a top surface of the second magnetic layer 160. The hard mask 120, the synthetic antiferromagnetic layer 130, the first magnetic layer 140 and the barrier layer 150 may hereby constitute a pillar. As formed, at least one portion 200 of the second magnetic layer 160 may extend from either side of the pillar in a horizontal plane, which portion(s) may be separated from the portion under the barrier layer 150, as illustrated in FIG. 1 and described further below.

To provide field-free switching in (SOT)-MTJ devices, the second magnetic (free) layer 160 of the MTJ stack 110 may comprise a plurality of portions, according to embodiments. For example, in the illustrated embodiment, the second magnetic layer 160 comprises an inner portion under the barrier layer 150 having an out-of-plane magnetic anisotropy and at least one outer portion having an in-plane magnetic anisotropy. The inner and outer portions of the second magnetic layer 160 may be physically separated from each other, either by one or more trenches (as shown in FIG. 1) or by one or more de-magnetized regions (as shown in FIG. 2).

By etching the stack of layers 110 to form the pillar of the MTJ device 100 in FIG. 1, at least one trench 210 may be created in the second magnetic layer 160. In the device 100, at least one first region of the portion(s) 200 of the second magnetic layer 160 extending from the pillar comprises a trench 210 adjacent and on either side of the pillar. In the illustrated embodiment, the trench 210 extends through an entire thickness of the second magnetic layer 160. However, embodiments are not so limited, and in other embodiments, the trench 210 may extend partially into the thickness of the second magnetic layer 160.

In some embodiments, the trench 210 may at least partially be coextensive with a side of the pillar. For example, the trench may have a length in the x-direction that is coextensive with a length of the pillar in the x-direction.

In some embodiments, the trench 210 may at least partially surround the pillar. For a pillar with a rectangular cross section, trenches or trench parts may accordingly be formed on all sides of the pillar. For a pillar with a round cross section, a single round trench extending about the pillar may be formed. It will be appreciated that the trench(es) 210, comprising perpendicular edges, are schematically shown for reasons of simplicity. In other words, it will be appreciated that the shapes of the trenches 210 obtained after etching may be highly irregular. The properties of the trench(es) 210 such as width, depth, length, profile, etc., may be relatively difficult to control during the etching process. However, examples of the width and depth of the trench(es) 210 may be approximately 4 nm.

Furthermore, by processing the portion(s) 200 of the second magnetic layer 160, at least one second region 220 of the portion(s) 200 may obtain an in-plane magnetic anisotropy. The processing of the portion(s) 200 may include oxidation, e.g., by subjecting the one or more portions 200 to an oxidizing environment, e.g., to O₂-plasma. For example, the processing may be performed in situ an etching machine, and the plasma may be generated from an oxygen gas. The portion(s) 200 may be subjected to the plasma for a predetermined period of time, which will influence the penetration depth of the oxygen into the material of the portion(s) 200.

Alternatively, or in addition to oxidation, the processing may include (ion) irradiation of the portion(s) 200. For example, the processing may be performed by accelerating ions (e.g., Gd ions) which penetrate into the material of the portions(s) 200.

In the MTJ device 100 in FIG. 1, there is provided at least one second region 220 peripheral to the at least one trench 210 with respect to the pillar in the x-direction, which has an in-plane magnetic anisotropy. It will be appreciated that the thickness of the second region(s) 220 may be thicker or thinner than the second magnetic layer 160.

Furthermore, after the etching of one or more trenches 210 of the second magnetic layer 160 of the MTJ device 100, there may be remnant material of the second magnetic layer 160 at the bottom of the trench(es) 210. In such situations, it may be desirable to de-magnetize at least a part of this remnant material such that a (completely) de-magnetized region is obtained. It will be appreciated that O₂-plasma may be used in the de-magnetization process, and the remnant material may be completely oxidized. Remnant material in the trench may in fact be de-magnetized during an O₂-plasma processing of the portion(s) 200.

Alternatively, or in combination herewith, an electrically insulating medium may be provided to the trench(es) 210. The electrically insulating medium may comprise a non-oxide compound, e.g., SiN.

FIG. 2 is a schematic view of a magnetic tunnel junction, MTJ, device 300, according to an alternative embodiment of the MTJ device 100 of FIG. 1. The device 300 comprises a stack 110 of layers analogously to the stack of layers 110 of device 100, and it is hereby referred to FIG. 1 for a more detailed description of the individual layers. However, instead of having one or more trenches, the second magnetic layer 160 comprises portions 310 located adjacent and on either side of the pillar, wherein the portions 310 are at least partially de-magnetized. It will be appreciated that the effect of providing de-magnetized portions 310 in the MTJ device 300 may be comparable to that of providing trenches according to the MTJ device 100 of FIG. 1, as both embodiments provide a de-magnetized region and/or separation between the inner and outer portions of the second magnetic layer of the MTJ device 100, 300. Alternatively, the portions 310 may comprise one or more electrically insulating media. For example, the portions 310 may comprise an oxide or a non-oxide compound, e.g., a nitride, such as SiN. The de-magnetized portions 310 may be created by subjecting the region of the second magnetic layer 160 adjacent to the pillar to a plasma, e.g., an O₂-plasma. The de-magnetization step may be performed after the above-described processing (e.g., by oxidation or irradiation) for forming the in-plane magnetization portion 220 of the second magnetic layer 160. During the de-magnetization step, the portions of the second magnetic layer 160 which are not to be de-magnetized (e.g., portions 220) may be masked to be protected from the demagnetizing condition, e.g., the O₂-plasma.

In a variation of the method and structure described in conjunction with FIG. 2, the stack of layers 110 may be etched until the barrier layer 150 is removed and stopped at a surface or in the second magnetic layer 160, or until the first magnetic layer 140 is removed and stopped at a surface of or in the barrier layer 150. Accordingly, at least the hard mask 120, the pinning layer/SAF layer 130 may constitute a pillar. Accordingly, the second magnetic layer 160, the barrier layer 150 and possibly also the first magnetic layer 140 may comprise respective portions located outside of the pillar, as viewed in the horizontal planes defined by the respective layers. Still, portions 220 of the second magnetic layer 160 presenting an in-plane magnetization, and de-magnetized portions 310 of the second magnetic layer 160 may be created by subjecting these portions to processing and de-magnetization steps, as described above. If the etch has been stopped already at the first magnetic layer 140, also the portions of the first magnetic layer 140 exposed by the pillar, and located above the portions 310, may be provided with a peripheral portion with an in-plane magnetization and a de-magnetized portion adjacent to the pillar.

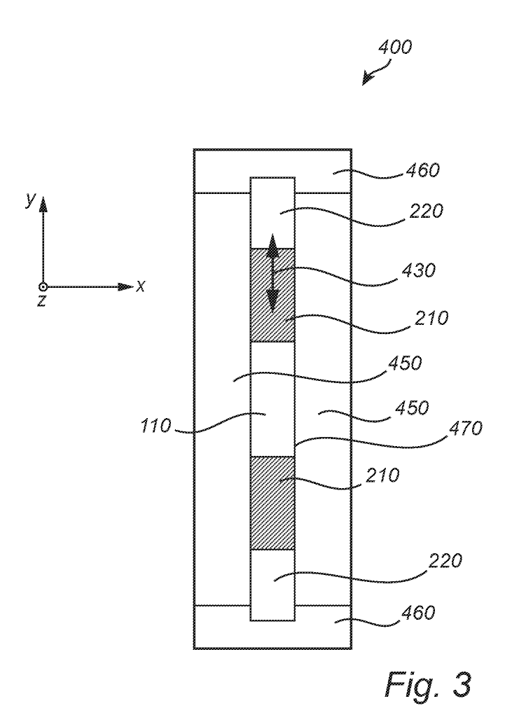

FIG. 3 is a schematic, top-view of an MTJ device 400 according to an embodiment of the MTJ device 100 of FIG. 1 or 300 of FIG. 2. Region 470 may comprise the stack of layers 110 and the SOT-generating layer 170. Between the stack of layers 110 and the two second regions 220 having an in-plane magnetic anisotropy, there may be provided trenches 210 according to FIG. 1 or portions 310 according to FIG. 2. Furthermore, a portion of the first magnetic layer 140 and/or the barrier layer 150 may be provided on the at least one second region 220, whereby the portion of the first magnetic layer 140 has been processed to be de-magnetized and insulating. The arrow 430 indicates the in-plane current of the MTJ device 400, the region 460 indicates the bottom electrode and region 450 indicates an insulating medium. The device 400 elongates in the direction of the in-plane current 430 (i.e. the y-direction), and the length of the device 400 in the y-direction may be larger than the height (i.e. in the z-direction) of the stack of the device 400. Furthermore, the length of the device 400 may be larger than the width (i.e. in the x-direction) of the stack of the device 400. It will be appreciated that this shape of the device 400 may create a de-magnetizing field which may orient the in-plane magnetic (shape) anisotropy along the direction of the current 430. Hence, the shape anisotropy will tend to naturally align the in-plane magnetization along the elongated axis. The de-magnetizing field should be larger in the x-direction than in the y-direction. In other words, the longitudinal direction should be larger than the transverse direction. Hence, there is an equivalency of applying a field along the longitudinal direction and forcing the magnetization to align with the longitudinal direction

The person skilled in the art realizes that the disclosed technology by no means is limited to the preferred embodiments described above. On the contrary, many modifications and variations are possible within the scope of the appended claims. For example, it will be appreciated that the figures are merely schematic views of MTJ devices according to embodiments of the disclosed technology. Hence, any layers of the MTJ devices 100, 300 may have different dimensions, shapes and/or sizes than those depicted and/or described. For example, one or more layers may be thicker or thinner than what is exemplified in the figures, the trench(es) may have other shapes, depths, etc., than that/those depicted. Furthermore, it will be appreciated that the techniques related to the masking, patterning and/or etching, may be different from those disclosed.

Although this invention has been described in terms of certain embodiments, other embodiments that are apparent to those of ordinary skill in the art, including embodiments that do not provide all of the features and advantages set forth herein, are also within the scope of this invention. Moreover, the various embodiments described above can be combined to provide further embodiments. In addition, certain features shown in the context of one embodiment can be incorporated into other embodiments as well. Accordingly, the scope of the present invention is defined only by reference to the appended claims.

What is claimed is:

1. A method of forming a magnetic tunnel junction (MTJ) device, the method comprising:
forming a stack of layers comprising, in a top-down direction towards a substrate:
a first magnetic layer having a fixed magnetization direction,
a barrier layer, and
a second magnetic layer having a switchable magnetization direction;
etching the stack of layers to form a pillar comprising at least the first magnetic layer;
forming at least one trench in the second magnetic layer adjacent to the pillar; and
processing at least one region of the second magnetic layer that is peripheral to the at least one trench with respect to the pillar, such that the at least one region has an in-plane magnetic anisotropy.

2. The method according to claim 1, wherein etching to form the pillar comprises stopping etching on the second magnetic layer, such that a portion of the second magnetic layer extends from the pillar in a horizontal plane, and wherein forming the at least one trench comprises patterning and etching the portion of the second magnetic layer.

3. The method according to claim 1, wherein forming the at least one trench comprises creating a trench on either side of the pillar, and wherein processing the at least one region of the second magnetic layer further comprises processing a respective region of the second magnetic layer that is peripheral to the respective trench with respect to the pillar, such that the respective region has an in-plane magnetic anisotropy.

4. The method according to claim 1, wherein a portion of the second magnetic layer remains at a bottom of the at least one trench after forming the at least one trench, and wherein the method further comprises de-magnetizing at least a part of the portion of the second magnetic layer remaining at the bottom of the at least one trench.

5. The method according to claim 1, further comprising forming an electrically insulating medium in the at least one trench.

6. The method according to claim 1, wherein processing the at least one region of the second magnetic layer comprises one or both of oxidizing and irradiating the at least one region.

7. The method according to claim 1, wherein each of the first magnetic layer and the second magnetic layer has an out-of-plane magnetic anisotropy.

8. The method according to claim 1, wherein etching the stack of layers further comprises etching the barrier layer.

9. A method of forming a magnetic tunnel junction (MTJ) device, the method comprising:
forming a stack of layers comprising, in a top-down direction towards a substrate:
a first magnetic layer having a fixed magnetization direction,
a barrier layer, and
a second magnetic layer having a switchable magnetization direction,
wherein forming the stack of layers further comprises forming a pinning layer on the first magnetic layer for fixing the magnetization direction of the first magnetic layer;
etching the stack of layers to form a pillar comprising at least the pinning layer;
processing a portion of the second magnetic layer extending outside the pillar in a horizontal plane, such that the portion has an in-plane magnetic anisotropy; and
de-magnetizing at least one region of the portion of the second magnetic layer adjacent to the pillar in a horizontal plane.

10. The method according to claim 9, wherein de-magnetizing further comprises de-magnetizing a respective region located on either side of the pillar.

11. The method according to claim 9, wherein etching the stack of layers to form the pillar further comprises etching the barrier layer.

12. A magnetic tunnel junction (MTJ) device, comprising:
a stack of layers comprising, in a top-down direction towards a substrate:
a first magnetic layer having a fixed magnetization direction,
a barrier layer, and
a second magnetic layer having a switchable magnetization direction,
wherein at least the first magnetic layer and the barrier layer form a pillar, and wherein a portion of the second magnetic layer extends from the pillar in a horizontal plane,
wherein at least one first region of the portion of the second magnetic layer comprises at least one trench that is adjacent to the pillar, and
wherein at least one second region of the portion of the second magnetic layer peripheral to the at least one trench with respect to the pillar has an in-plane magnetic anisotropy.

13. The device according to claim 12, further comprising a trench on either side of the pillar and a respective second region that is peripheral to the respective trench.

14. The device according to claim 12, wherein, a portion of the second magnetic layer is present at a bottom of the at least one trench, and wherein at least a part of the portion of the second magnetic layer is de-magnetized.

15. The device according to claim 12, wherein at least one of the trenches is at least partially provided with an electrically insulating medium.

16. The device according to claim 12, wherein each of the first magnetic layer and the second magnetic layer has an out-of-plane magnetic anisotropy.

17. The device according to claim 12, wherein the at least one trench surrounds the pillar.

18. A magnetic tunnel junction (MTJ) device, comprising:
a stack of layers comprising, in a top-down direction towards a substrate:
a first magnetic layer having a fixed magnetization direction,
a barrier layer, and
a second magnetic layer having a switchable magnetization direction,
wherein the stack of layers further includes a pinning layer formed on the first magnetic layer for fixing the magnetization direction of the first magnetic layer,
wherein at least the pinning layer is formed as a pillar,
wherein the second magnetic layer comprises at least one first portion located outside the pillar, as viewed in a horizontal plane, the at least one first portion being de-magnetized, and
wherein the second magnetic layer comprises at least one second portion located peripheral to the at least one first portion with respect to the pillar, the at least one second portion having an in-plane magnetic anisotropy.

19. The device according to claim 18, wherein the second magnetic layer comprises one of the at least one first portion located on either side of the pillar and one of the at least one second portion peripheral of a respective one of the at least one first portion.

20. The device according to claim 18, wherein at least one of a width and a length of the device in a plane thereof is larger than a height of the stack of layers.
